(19) United States
(12) Patent Application Publication
(10) Pub. No.: US 2024/0112974 A1
(43) Pub. Date: Apr. 4, 2024

(54) SEMICONDUCTOR PACKAGE

(71) Applicant: Samsung Electronics Co., Ltd., Suwon-si (KR)

(72) Inventor: Min Sek Jang, Suwon-si (KR)

(21) Appl. No.: 18/320,513

(22) Filed: May 19, 2023

(30) Foreign Application Priority Data
Oct. 4, 2022 (KR) 10-2022-0126365
Oct. 21, 2022 (KR) 10-2022-0136120

(51) Int. Cl. H01L 23/31; H01L 23/00; H01L 23/498; H01L 25/10

(52) U.S. Cl. CPC H01L 23/3135; H01L 23/49816; H01L 23/49822; H01L 23/49838; H01L 24/08; H01L 24/16; H01L 24/32; H01L 24/73; H01L 25/105; H01L 2224/08235; H01L 2224/16225; H01L 2224/32225; H01L 2224/73204; H01L 2225/1041; H01L 2225/1058; H01L 2924/15174

(57) ABSTRACT

A semiconductor package includes a first redistribution structure including a first redistribution layer, a first semiconductor chip on the first redistribution structure, an insulating layer adjacent a sidewall of the first semiconductor chip on the first redistribution structure and spaced apart from the first semiconductor chip in a horizontal direction, a connection structure extending through the insulating layer in a vertical direction and electrically connected to the first redistribution layer, a first molding layer on a sidewall and a top surface of the first semiconductor chip, and a second molding layer directly on each of a top surface of the insulating layer and a top surface of the first molding layer. The second molding layer includes a material different from a material of the first molding layer, and the top surface of the first semiconductor chip is lower than the top surface of the insulating layer.

### CROSS-REFERENCE TO RELATED APPLICATION

This application claims priority from Korean Patent Application No. 10-2022-0126365 filed on Oct. 4, 2022 and No. 10-2022-0136120 filed on Oct. 21, 2022 in the Korean Intellectual Property Office, and all the benefits accruing therefrom under 35 U.S.C. 119, the contents of which in its entirety are herein incorporated by reference.

### FIELD

The present disclosure relates to a semiconductor package manufactured using a fan-out panel level package process.

### BACKGROUND

There may be demand for high-performance elements, which may require a size of a semiconductor chip (and, accordingly, a size of a semiconductor package) to increase. Conversely, a thickness of the semiconductor package may need to decrease due to demand for slimmer electronic devices.

A fan-out panel level package has a structure in which a semiconductor chip is mounted into a cavity and then a molding layer is formed thereon. In the fan-out panel level package, a molding process may be performed across an entire panel to secure insulating properties.

### SUMMARY

Embodiments of the present disclosure may provide a semiconductor package manufactured using a fan-out panel level package process in which a vertical level of a top surface of a semiconductor chip is lower than that of a top surface of an insulating layer constituting a core substrate.

Further embodiments of the present disclosure may provide a semiconductor package manufactured using a fan-out panel level package process in which a semiconductor chip is formed in a recess defined in an insulating layer constituting a core substrate, and a first molding layer with a relatively low viscosity is formed in the recess and on the semiconductor chip, and a second molding layer having a relatively higher viscosity than that of the first molding layer is formed to cover the first molding layer and the insulating layer, thereby providing the semiconductor package having a reduced thickness.

According to some embodiments of the present disclosure, there is provided a semiconductor package, comprising a first redistribution structure including a first redistribution layer, a first semiconductor chip on the first redistribution structure, an insulating layer adjacent a sidewall of the first semiconductor chip on the first redistribution structure, the insulating layer is spaced apart from the first semiconductor chip in a horizontal direction, a connection structure extending through the insulating layer in a vertical direction, the connection structure is electrically connected to the first redistribution layer, a first molding layer on a sidewall and a top surface of the first semiconductor chip, and a second molding layer directly on each of a top surface of the insulating layer and a top surface of the first molding layer, the second molding layer includes a material different from a material of the first molding layer, wherein the top surface of the first semiconductor chip is lower than the top surface of the insulating layer relative to the first redistribution structure.

According to some embodiments of the present disclosure, there is provided a semiconductor package, comprising a first redistribution structure including a first redistribution layer, an insulating layer on the first redistribution structure, a recess in the insulating layer, a first semiconductor chip in the recess, and spaced apart from the insulating layer in a horizontal direction, a top surface of the first semiconductor chip is lower than a top surface of the insulating layer relative to the first redistribution structure, a first molding layer on a sidewall and the top surface of the first semiconductor chip in the recess, the first molding layer is free of a filling material including silicon (Si) particles, and a second molding layer directly on each of the top surface of the insulating layer and a top surface of the first molding layer, the second molding layer includes the filling material including silicon (Si) particles.

According to some embodiments of the present disclosure, there is provided a semiconductor package, comprising a first redistribution structure including a first redistribution layer, a first semiconductor chip on the first redistribution structure, an insulating layer adjacent a sidewall of the first semiconductor chip on the first redistribution structure, the insulating layer is spaced apart from the first semiconductor chip in a horizontal direction, a connection structure extending through the insulating layer in a vertical direction, the connection structure is electrically connected to the first redistribution layer, a first molding layer on the sidewall and a top surface of the first semiconductor chip, the first molding layer is free of a filling material including silicon (Si) particles, the first molding layer does not contact the connection structure, a second molding layer directly on each of a top surface of the insulating layer and a top surface of the first molding layer, the second molding layer directly contacts at least a portion of the connection structure, the second molding layer includes the filling material including silicon (Si) particles, and a second redistribution structure on the second molding layer, the second redistribution structure includes a second redistribution layer, wherein the top surface of the first semiconductor chip is lower than the top surface of the insulating layer relative to the first redistribution structure, and wherein the top surface of the first molding layer is coplanar with the top surface of the insulating layer.

Embodiments of the present disclosure are not limited to those mentioned above. Other advantages according to the present disclosure that are not mentioned may be understood based on following description, and may be more clearly understood based on embodiments according to the present disclosure and any combinations thereof.

### BRIEF DESCRIPTION OF DRAWINGS

The above and other aspects and features of the present disclosure will become more apparent by describing in detail embodiments thereof with reference to the attached drawings, in which:

FIG. 1 is a diagram illustrating a semiconductor package according to some embodiments of the present disclosure;

FIG. 2 is an enlarged view of a region S1 of FIG. 1;

FIGS. 3 to 15 are diagrams of intermediate structures corresponding to intermediate steps illustrating a method for manufacturing a semiconductor package according to some embodiments of the present disclosure;

FIG. 16 is a diagram illustrating a semiconductor package according to further embodiments of the present disclosure;

FIG. 17 is an enlarged view of a region S2 of FIG. 16;

FIG. 18 is a diagram illustrating a semiconductor package according to still further embodiments of the present disclosure;

FIG. 19 is an enlarged view of a region S3 of FIG. 18;

FIG. 20 is a diagram illustrating a semiconductor package according to still yet further embodiments of the present disclosure;

FIG. 21 is an enlarged view of a region S4 of FIG. 20;

FIG. 22 is a diagram illustrating a semiconductor package according to still yet further embodiments of the present disclosure;

FIG. 23 is an enlarged view of a region S5 of FIG. 22;

FIG. 24 is a diagram illustrating a semiconductor package according to still yet further embodiments of the present disclosure;

FIG. 25 is a diagram illustrating a semiconductor package according to still yet further embodiments of the present disclosure; and

FIG. 26 is a diagram illustrating a semiconductor package according to still yet further embodiments of the present disclosure.

### DETAILED DESCRIPTION OF EMBODIMENTS

Hereinafter, embodiments of the present disclosure will be described in detail with reference to the accompanying drawings. The same reference numerals are used for the same components in the drawings, and duplicate descriptions thereof are omitted.

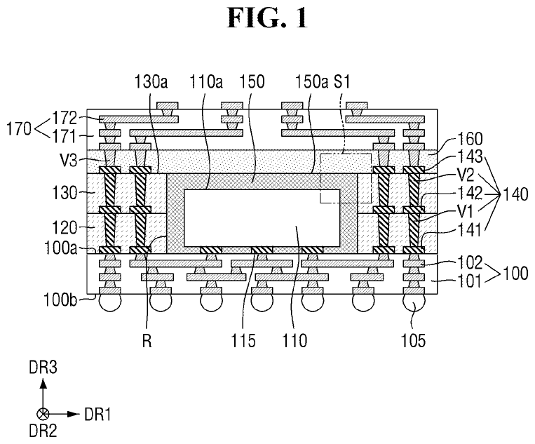

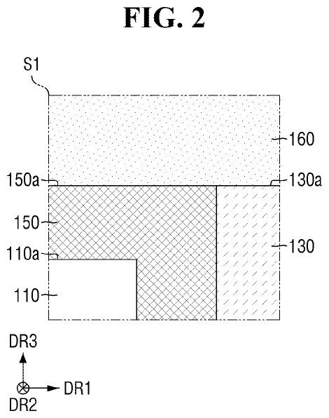

Hereinafter, a semiconductor package according to some embodiments of the present disclosure will be described with reference to FIG. 1 and FIG. 2.

FIG. 1 is a diagram illustrating a semiconductor package according to some embodiments of the present disclosure. FIG. 2 is an enlarged view of a region S1 of FIG. 1.

Referring to FIG. 1 and FIG. 2, the semiconductor package according to some embodiments of the present disclosure includes a first redistribution structure 100, a first solder ball 105, a first semiconductor chip 110, a first insulating layer 120, a second insulating layer 130, a connection structure 140, a first molding layer 150, a second molding layer 160 and a second redistribution structure 170. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements.

The first redistribution structure 100 may include a first surface 100a and a second surface 100b opposite the first surface 100a. For example, in FIG. 1, the first surface 100a of the first redistribution structure 100 may be defined as a top surface of the first redistribution structure 100, while the second surface 100b of the first redistribution structure 100 may be defined as a bottom of the first redistribution structure 100.

Hereinafter, each of a first horizontal direction DR1 and a second horizontal direction DR2 may be defined as a direction parallel to the first surface 100a of the first redistribution structure 100. The second horizontal direction DR2 may be defined as a different direction from the first horizontal direction DR1. A vertical direction DR3 may be defined as a direction perpendicular to a plane defined by the first horizontal direction DR1 and the second horizontal direction DR2. That is, the vertical direction DR3 may be defined as a direction perpendicular to the first surface 100a of the first redistribution structure 100.

The first redistribution structure 100 may include a first interlayer insulating film 101 and a first redistribution layer 102. The first redistribution layer 102 may be disposed inside the first interlayer insulating film 101. The first redistribution layer 102 may include a plurality of wirings spaced apart from each other in each of the first horizontal direction DR1 and the second horizontal direction DR2. Further, the first redistribution layer 102 may include a plurality of wirings spaced apart from each other in the vertical direction DR3.

The first redistribution layer 102 may include a conductive material. The first redistribution layer 102 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), or zirconium (Zr).

The first interlayer insulating film 101 may include an insulating material. The first interlayer insulating film 101 may include, for example, PID (photo imagable dielectric). That is, the first interlayer insulating film 101 may include a photosensitive insulating material. The first interlayer insulating film 101 may include, for example, an epoxy resin or polyimide. However, the present disclosure is not limited thereto.

The first solder balls 105 may be disposed on the second surface 100b of the first redistribution structure 100. The term “connected” may be used herein to refer to a physical and/or electrical connection. The first solder ball 105 may be connected to the exposed first redistribution layer 102 on the second surface 100b of the first redistribution structure 100. The first solder ball 105 may refer to a portion via which the first redistribution structure 100 is electrically connected to an external element. The first solder ball 105 may include, for example, at least one of tin (Sn), indium (In), lead (Pb), zinc (Zn), nickel (Ni), gold (Au), silver (Ag), copper (Cu), antimony (Sb), bismuth (Bi), or combinations thereof. However, the present disclosure is not limited thereto.

The first insulating layer 120 may be disposed on the first surface 100a of the first redistribution structure 100. For example, the first insulating layer 120 may contact the first surface 100a of the first redistribution structure 100. When components or layers are referred to herein as “directly on” or “directly contact” or “in direct contact with,” no intervening components or layers are present. The second insulating layer 130 may be disposed on the first insulating layer 120. For example, the second insulating layer 130 may partially or entirely overlap with the first insulating layer 120 in the vertical direction DR3. Components or layers described with reference to “overlap” in a particular direction may be at least partially obstructed by one another when viewed along a line extending in the particular direction or in a plane perpendicular to the particular direction. For example, the second insulating layer 130 may contact the first insulating layer 120.

Although FIG. 1 illustrates that two insulating layers 120 and 130 are disposed on the first surface 100a of the first redistribution structure 100, the present disclosure is not limited thereto. In some further embodiments, one insulating layer may be disposed on the first surface 100a of the first redistribution structure 100. Further, in some embodiments, three or more insulating layers may be disposed on the first surface 100a of the first redistribution structure 100.

For example, a sidewall of each of the first insulating layer 120 and the second insulating layer 130 may be aligned with a sidewall of the first redistribution structure 100 in the vertical direction DR3. Each of the first insulating layer 120 and the second insulating layer 130 may include an insulating material. Each of the first insulating layer 120 and the second insulating layer 130 may include, for example, at least one of epoxy resin, polyimide, or PPG (prepreg), ABF (Ajinomoto Build-up Film), FR-4, or BT (Bismaleimide Triazine). However, the present disclosure is not limited thereto.

A recess R may be defined inside each of the first and second insulating layers 120 and 130 while being disposed on the first surface 100a of the first redistribution structure 100. That is, the recess R may extend through each of the first and second insulating layers 120 and 130 in the vertical direction DR3 so as to expose the first surface 100a of the first redistribution structure 100. The recess R may be defined by the first surface 100a of the first redistribution structure 100, a sidewall of the first insulating layer 120, and a sidewall of the second insulating layer 130. That is, the recess R may be surrounded by the first insulating layer 120 and the second insulating layer 130.

The first semiconductor chip 110 may be disposed on the first surface 100a of the first redistribution structure 100. The first semiconductor chip 110 may be disposed inside the recess R. The first semiconductor chip 110 may be surrounded by each of the first insulating layer 120 and the second insulating layer 130. For example, the first semiconductor chip 110 may be spaced apart from each of the first insulating layer 120 and the second insulating layer 130 in the first horizontal direction DR1. Although not shown in FIG. 1, for example, the first semiconductor chip 110 may be spaced apart from each of the first insulating layer 120 and the second insulating layer 130 in the second horizontal direction DR2. A vertical level of a top surface 110a of the first semiconductor chip 110 may be lower than that of a top surface 130a of the second insulating layer 130. That is, the top surface 110a of the first semiconductor chip 110 may be closer to the first surface 100a of the first redistribution structure 100 than the top surface 130a of the second insulating layer 130. Spatially relative terms, such as “beneath,” “below,” “lower,” “above,” “upper,” and the like, may be used herein to describe one element's or feature's relationship to another as illustrated in the figures, but are intended to encompass different orientations of the device in use or operation in addition to the orientation depicted in the figures. For example, if the device in the figures is turned over, elements described as “below” or “beneath” other elements or features would then be oriented “above” the other elements or features. FIG. 1 illustrates that the vertical level of the top surface 110a of the first semiconductor chip 110 is higher than that of a top surface of the first insulating layer 120. However, the present disclosure is not limited thereto. In further some embodiments, the vertical level of the top surface 110a of the first semiconductor chip 110 may be lower than that of the top surface of the first insulating layer 120.

For example, the first semiconductor chip 110 may be embodied as a logic semiconductor chip. For example, the first semiconductor chip 110 may be embodied as an application processor (AP) such as CPU (Central Processing Unit), GPU (Graphic Processing Unit), FPGA (Field-Programmable Gate Array), DSP (Digital Signal Processor), CP (Cryptographic Processor), a microprocessor, a microcontroller, or ASIC (Application-Specific IC), etc.

For example, the first semiconductor chip 110 may be embodied as a memory semiconductor chip. For example, the first semiconductor chip 110 may be embodied as a volatile memory such as DRAM (dynamic random access memory) or SRAM (static random access memory), or may be a non-volatile memory such as a flash memory, PRAM (Phase-change Random Access Memory), MRAM (Magnetoresistive Random Access Memory), FeRAM (Ferroelectric Random Access Memory) or RRAM (Resistive Random Access Memory).

A semiconductor chip connection pad 115 may be disposed between the first surface 100a of the first redistribution structure 100 and the first semiconductor chip 110. The semiconductor chip connection pad 115 may be connected to the first redistribution layer 102. The first semiconductor chip 110 may be electrically connected to the first redistribution structure 100 via the semiconductor chip connection pad 115. The semiconductor chip connection pad 115 may include a conductive material.

Each of a plurality of connection structures 140 may extend through each of the first insulating layer 120 and the second insulating layer 130 in the vertical direction DR3 and thus may be connected to the first redistribution layer 102. For example, the plurality of connection structures 140 may be disposed on or adjacent each of both opposing sidewalls in the first horizontal direction DR1 of the first semiconductor chip 110. Further, the plurality of connection structures 140 may be disposed on or adjacent each of both opposing sidewalls in the second horizontal direction DR2 of the first semiconductor chip 110.

For example, each of the plurality of connection structures 140 may include first to third connection pads 141, 142, and 143, and first and second vias V1 and V2. For example, the first connection pad 141 may be disposed on the first surface 100a of the first redistribution structure 100. The first connection pad 141 may be connected to the first redistribution layer 102. The first connection pad 141 may be disposed inside the first insulating layer 120. For example, a sidewall and a top surface of the first connection pad 141 may contact the first insulating layer 120.

For example, the second connection pad 142 may be disposed on a top surface of the first insulating layer 120. The second connection pad 142 may be disposed inside the second insulating layer 130. For example, a sidewall and a top surface of the second connection pad 142 may contact the second insulating layer 130. At least a portion of a bottom surface of the second connection pad 142 may be in contact with the first insulating layer 120. For example, the third connection pad 143 may be disposed on a top surface of the second insulating layer 130. At least a portion of a bottom surface of the third connection pad 143 may be in contact with the top surface of the second insulating layer 130.

For example, the first via V1 may be disposed inside the first insulating layer 120. The first via V1 may extend in the vertical direction DR3 so as to connect the first connection pad 141 and the second connection pad 142 to each other. For example, the second via V2 may be disposed inside the second insulating layer 130. The second via V2 may extend in the vertical direction DR3 so as to connect the second connection pad 142 and the third connection pad 143 to each other.

Each of the first to third connection pads 141, 142 and 143, and the first and second vias V1 and V2 may include a conductive material. For example, each of the first to third connection pads 141, 142 and 143, and the first and second vias V1 and V2 may include a metal material such as copper (Cu), aluminum (Al), silver (Ag), tin (Sn), gold (Au), nickel (Ni), lead (Pb), titanium (Ti), or alloys thereof. However, the present disclosure is not limited thereto.

The first molding layer 150 may be disposed inside the recess R. The first molding layer 150 may extend on or cover a sidewall and a top surface of the first semiconductor chip 110 while being disposed the inside of the recess R. A portion of the first molding layer 150 disposed between the first surface 100a of the first redistribution structure 100 and a bottom surface of the first semiconductor chip 110 may surround a sidewall of the semiconductor chip connection pad 115. The first molding layer 150 may contact each of the sidewall of the first insulating layer 120, the sidewall of the second insulating layer 130, and the sidewall and the top surface of the first semiconductor chip 110 while being disposed inside the recess R.

For example, a top surface 150a of the first molding layer 150 may be coplanar with a top surface 130a of the second insulating layer 130. The first molding layer 150 is not in contact with each of the plurality of connecting structures 140. For example, the first molding layer 150 may not contact the top surface 130a of the second insulating layer 130. The first molding layer 150 may include an insulating material. For example, the first molding layer 150 may include, as a base material, PIE (Photo Imagable Encapsulant), an epoxy molding compound (EMC) or a hybrid material of two or more types of silicon in a form of a film. For example, the first molding layer 150 is free of a filling material including silicon (Si) particles.

The second molding layer 160 may be disposed on each of the top surface 130a of the second insulating layer 130 and the top surface 150a of the first molding layer 150. The second molding layer 160 may contact each of the top surface 130a of the second insulating layer 130 and the top surface 150a of the first molding layer 150. For example, the second molding layer 160 may contact at least a portion of the connection structure 140 protruding from the top surface 130a of the second insulating layer 130 in the vertical direction DR3. That is, the second molding layer 160 may be in contact with a sidewall and a top surface of the third connection pad 143.

The second molding layer 160 may include an insulating material. For example, the second molding layer 160 may include, as a base material, PIE (Photo Imagable Encapsulant), an epoxy molding compound (EMC) or a hybrid material of two or more types of silicon in a form of a film. For example, the second molding layer 160 may include the same base material as that of the first molding layer 150. However, the present disclosure is not limited thereto.

The second molding layer 160 may contain a filling material including silicon (Si) particles. Even when the first molding layer 150 and the second molding layer 160 include the same base material, the first molding layer 150 is free of the filling material including the silicon (Si) particles, while the second molding layer 160 contains the filling material including the silicon (Si) particles. Thus, the first molding layer 150 and the second molding layer 160 may be made of different materials.

A viscosity of the first molding layer 150 not containing the filling material including the silicon (Si) particles may be lower than a viscosity of the second molding layer 160 containing the filling material including the silicon (Si) particles. Thus, the first molding layer 150 may effectively fill the recess R.

A third via V3 may extend through the second molding layer 160 in the vertical direction DR3 so as to be connected to a respective one of the plurality of connection structures 140. The third vias V3 respectively connected to the plurality of connection structures 140 may be spaced apart from each other. The third via V3 may include a conductive material. For example, the third via V3 may include a metal material such as copper (Cu), aluminum (Al), silver (Ag), tin (Sn), gold (Au), nickel (Ni), lead (Pb), titanium (Ti), or alloys thereof. However, the present disclosure is not limited thereto.

The second redistribution structure 170 may be disposed on a top surface of the second molding layer 160. The second redistribution structure 170 may be electrically connected to each of the connection structures 140 via each of the third vias V3. The second redistribution structure 170 may include a second interlayer insulating film 171 and a second redistribution layer 172. The second redistribution layer 172 may be disposed inside the second interlayer insulating film 171. The second redistribution layer 172 may include a plurality of wirings spaced apart from each other in each of the first horizontal direction DR1 and the second horizontal direction DR2. Further, the second redistribution layer 172 may include a plurality of wirings spaced apart from each other in the vertical direction DR3.

Although it is illustrated in FIG. 1 that a portion of the second redistribution layer 172 protrudes from a top surface of the second interlayer insulating film 171 in the vertical direction DR3, the present disclosure is not limited thereto. For example, a sidewall of the second redistribution structure 170 may be aligned with each of a sidewall of the second molding layer 160, a sidewall of the first insulating layer 120, a sidewall of the second insulating layer 130, and a sidewall of the first redistribution structure 100 in the vertical direction DR3.

The second redistribution layer 172 may include a conductive material. The second redistribution layer 172 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al) or zirconium (Zr).

The second interlayer insulating film 171 may include an insulating material. The second interlayer insulating film 171 may include, for example, a PID (photo imagable dielectric). That is, the second interlayer insulating film 171 may include a photosensitive insulating material. The second interlayer insulating film 171 may include, for example, epoxy resin or polyimide. However, the present disclosure is not limited thereto.

Hereinafter, a method for manufacturing a semiconductor package according to some embodiments of the present disclosure will be described with reference to FIGS. 1 to 15.

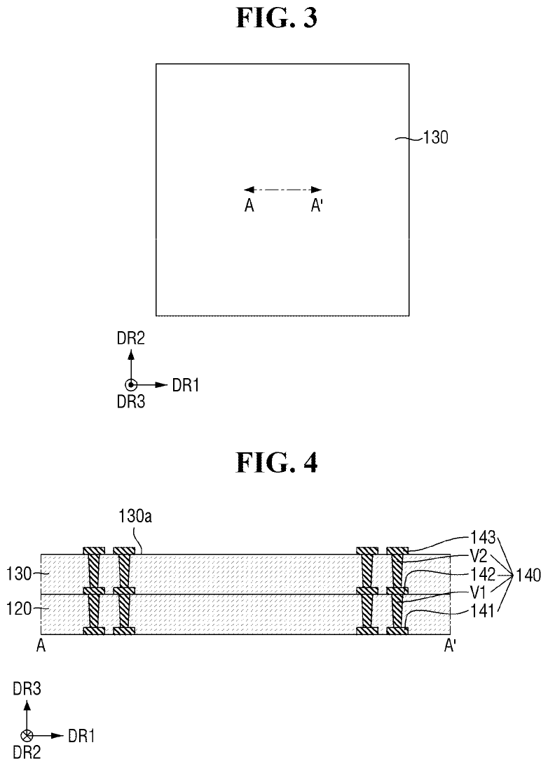

FIGS. 3 to 15 are diagrams of intermediate structures corresponding to intermediate steps illustrating a method for manufacturing a semiconductor package according to some embodiments of the present disclosure.

Referring to FIG. 3 and FIG. 4, the first insulating layer 120 and the second insulating layer 130 in which the plurality of connection structures 140 spaced apart from each other in each of the first and second horizontal directions DR1 and DR2 are formed may be formed. For example, the first insulating layer 120 and the second insulating layer 130 may be formed at a level of a panel formed by cutting a wafer.

For example, the first insulating layer 120 and a portion of each of the plurality of connection structures 140 may be formed. In this regard, the portion of each of the plurality of connection structures 140 may include the first connection pad 141 and the first via V1 of FIG. 1. The portion of each of the plurality of connection structures 140 may be formed inside the first insulating layer 120.

Subsequently, the second insulating layer 130 and a remaining portion of each of the plurality of connection structures 140 may be formed on the first insulating layer 120. In this regard, the remaining portion of each of the plurality of connection structures 140 may include the second connection pad 142, the second via V2, and the third connection pad 143 of FIG. 1. For example, each of the second connection pad 142 and the second via V2 may be formed inside the second insulating layer 130. For example, the third connection pad 143 may be formed on a top surface of the second insulating layer 130.

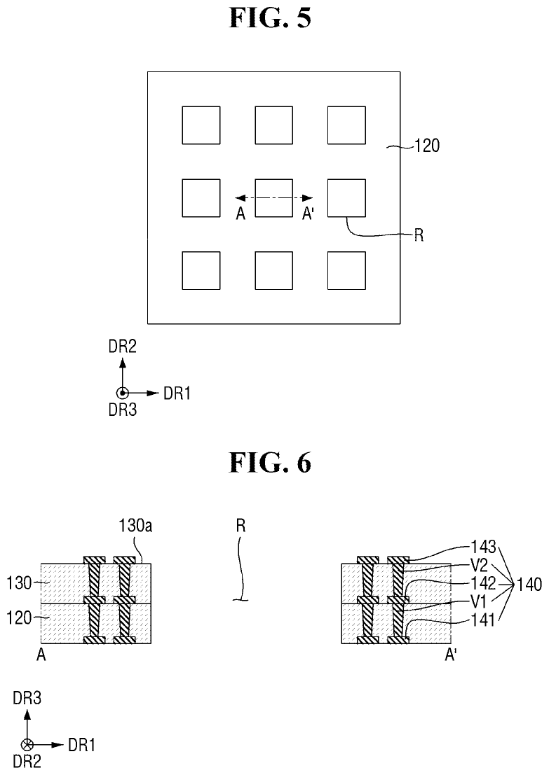

Referring to FIG. 5 and FIG. 6, each of a plurality of recesses R may be formed between the plurality of connection structures 140. For example, each of the plurality of recesses R may be formed by etching each of the first insulating layer 120 and the second insulating layer 130 in a region where each of the plurality of connection structures 140 is not formed. For example, the plurality of recesses R may be spaced apart from each other in each of the first horizontal direction DR1 and the second horizontal direction DR2.

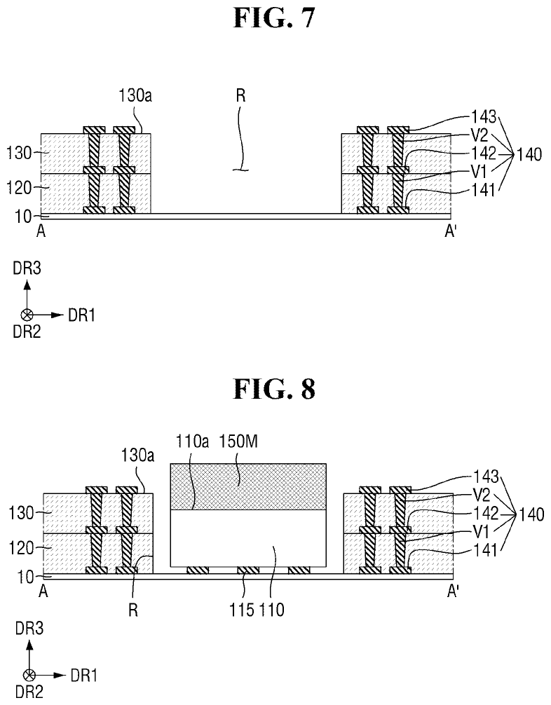

Referring to FIG. 7, a tape 10 may be attached to a bottom surface of the first insulating layer 120. The tape 10 may constitute the bottom surface of the recess R.

Referring to FIG. 8, a molding material layer 150M may be formed on a top surface 110a of the first semiconductor chip 110. The molding material layer 150M may include an insulating material. For example, the molding material layer 150M may include, as a base material, PIE (Photo Imagable Encapsulant), an epoxy molding compound (EMC) or a hybrid material of two or more types of silicon in a form of a film. For example, the molding material layer 150M is free of a filling material including silicon (Si) particles.

Subsequently, the first semiconductor chip 110 on which the molding material layer 150M has been formed may be mounted in the recess R. The first semiconductor chip 110 may be attached to the tape 10 using the semiconductor chip connection pad 115. The first semiconductor chip 110 and the molding material layer 150M may be respectively spaced apart from the first insulating layer 120 and the second insulating layer 130 in the first horizontal direction DR1 and the second horizontal direction DR2, respectively.

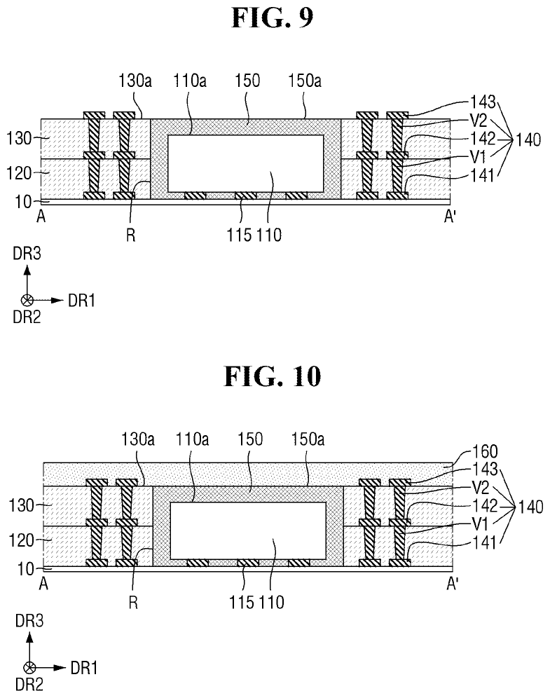

Referring to FIG. 9, pressure and heat may be applied to the molding material layer 150M. Under the process in which the pressure and heat are applied, the molding material layers 150M may fill each of a space between the first insulating layer 120 and the first semiconductor chip 110, a space between the second insulating layer 130 and the first semiconductor chip 110, and a space between the tape 10 and the first semiconductor chip 110 inside the recess R. In this case, the molding material layer 150M has a relatively lower viscosity such that the molding material layer 150M may effectively fill the recess R. The molding material layer 150M may not contain the filling material including silicon (Si) particles and thus have the relatively lower viscosity.

After the process of applying the pressure and heat to the molding material layer 150M has been performed, the molding material layer 150M may be converted to the first molding layer 150. The top surface 150a of the first molding layer 150 may be coplanar with the top surface 130a of the second insulating layer 130.

Referring to FIG. 10, the second molding layer 160 may be formed on the top surface 130a of the second insulating layer 130 and on the top surface 150a of the first molding layer 150. The second molding layer 160 may include an insulating material. For example, the second molding layer 160 may include, as a base material, PIE (Photo Imagable Encapsulant), an epoxy molding compound (EMC) or a hybrid material of two or more types of silicon in a form of a film. For example, the second molding layer 160 may contain a filling material including silicon (Si) particles. Thus, the second molding layer 160 may have a higher viscosity than that of the first molding layer 150.

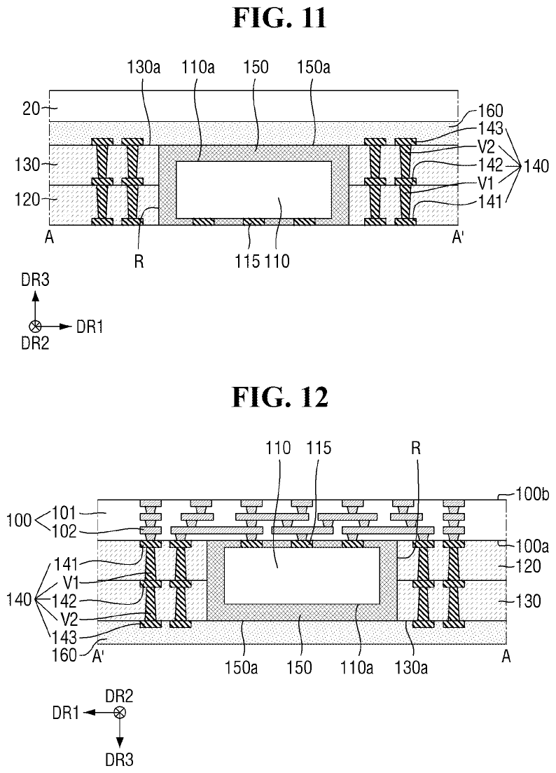

Referring to FIG. 11, a first carrier substrate 20 may be attached onto a top surface of the second molding layer 160. Subsequently, the tape (10 of FIG. 10) may be removed.

Referring to FIG. 12, an intermediate structure as shown in FIG. 11 may be turned upside down so that the first carrier substrate (20 in FIG. 11) faces downwardly. Subsequently, the first carrier substrate (20 in FIG. 11) may be removed.

The first redistribution structure 100 may be formed on the first insulating layer 120 and the first molding layer 150. The first redistribution structure 100 may include the first interlayer insulating film 101 and the first redistribution layer 102 formed inside the first interlayer insulating film 101. Each of the plurality of connection structures 140 and the semiconductor chip connection pads 115 may be electrically connected to the first redistribution layer 102. The first semiconductor chip 110 may be electrically connected to the first redistribution layer 102 via the semiconductor chip connection pad 115.

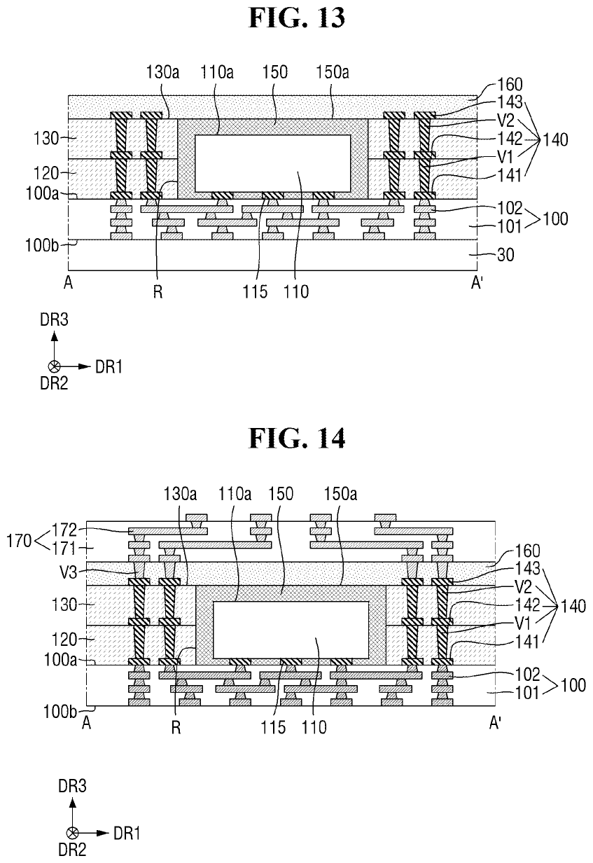

Referring to FIG. 13, a second carrier substrate 30 may be placed on the second surface 100b of the first redistribution structure 100. Then, an intermediate structure as shown in FIG. 12 may be turned upside down so that the second carrier substrate 30 faces downwardly.

Referring to FIG. 14, the second carrier substrate (30 in FIG. 13) may be removed. The third via V3 may be formed so as to extend through the second molding layer 160 in the vertical direction DR3 and to be connected to each of the plurality of connection structures 140. The second redistribution structure 170 may be formed on the second molding layer 160. The second redistribution structure 170 may include the second interlayer insulating film 171 and the second redistribution layer 172 formed inside the second interlayer insulating film 171. The third via V3 may be electrically connected to the second redistribution layer 172. Each of the plurality of connection structures 140 may be electrically connected to the second redistribution layer 172 through respective ones of the third vias V3.

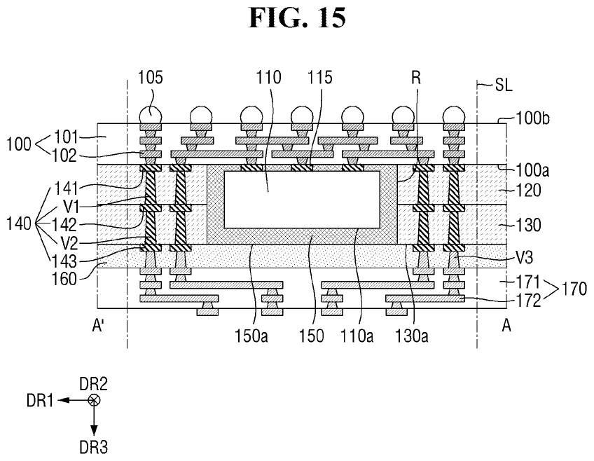

Referring to FIG. 15, an intermediate structure as shown in FIG. 14 may be turned upside down so that the second redistribution structure 170 faces downwardly. Subsequently, the first solder balls 105 may be formed on the second surface 100b of the first redistribution structure 100. The first solder ball 105 may be connected to the first redistribution layer 102 not covered with the second surface 100b of the first redistribution structure 100 so as to be exposed.

Subsequently, a cutting (sawing) process may be performed. For example, the first redistribution structure 100, the first insulating layer 120, the second insulating layer 130, the second molding layer 160, and the second redistribution structure 170 may be cut along a scribe line SL extending in the vertical direction DR3. After the cutting (sawing) process has been completed, a resulting structure is turned upside down. Thus, the semiconductor package as shown in FIG. 1 may be manufactured.

A semiconductor package and a method for manufacturing a semiconductor package according to some embodiments of the present disclosure relate to a semiconductor package manufactured using a fan-out panel level package process. In the semiconductor package and the method for manufacturing the semiconductor package according to some embodiments of the present disclosure, the recess R may be formed in the first insulating layer 120 and the second insulating layer 130 that constitute a core substrate, and then the semiconductor chip 110 may be formed inside the recess R such that the vertical level of the top surface 110a of the chip 110 may be lower than that of the top surface 130a of the second insulating layer 130.

Further, pressure and heat may be applied to the first molding layer 150 including the insulating material disposed on the semiconductor chip 110 such that first molding layer 150 may be formed inside the recess R so as to cover the semiconductor chip 110. Subsequently, the second molding layer 160 including the material different from the material of the first molding layer 150 may be formed to cover the first molding layer 150 and the second insulating layer 130. The first molding layer 150 may include a material having a lower viscosity than that of the material of the second molding layer 160.

In the semiconductor package and the method for manufacturing the semiconductor package according to some embodiments of the present disclosure, the pressure and heat may be applied to the first molding layer 150 having the relatively lower viscosity such that the first molding layer 150 may be formed inside the recess R so as to cover the semiconductor chip 110. Thus, a thickness of the first molding layer 150 may be reduced. In this way, a total thickness of the semiconductor package according to some embodiments of the present disclosure may be reduced.

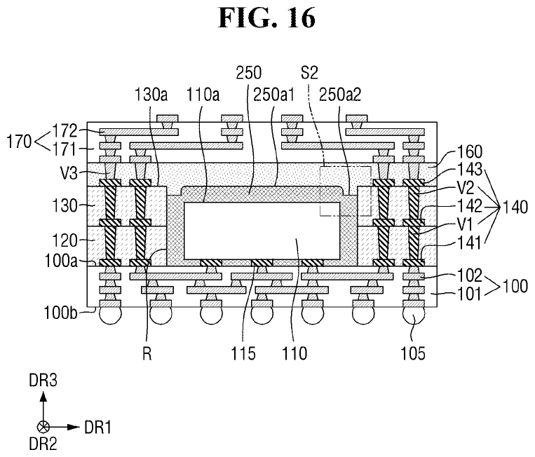

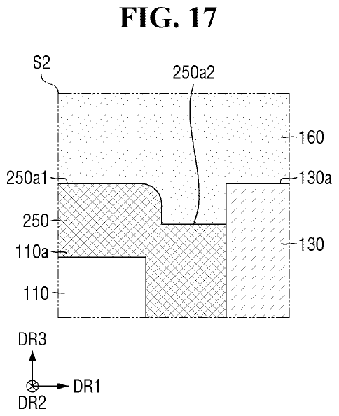

Hereinafter, a semiconductor package according to further some embodiments of the present disclosure will be described with reference to FIGS. 16 and 17. The following descriptions will focus on differences from the semiconductor package as shown in FIG. 1 and FIG. 2.

FIG. 16 is a diagram illustrating a semiconductor package according to further embodiments of the present disclosure. FIG. 17 is an enlarged view of a region S2 of FIG. 16.

Referring to FIG. 16 and FIG. 17, a first molding layer 250 of the semiconductor package according to further some embodiments of the present disclosure may include a first top surface 250a1 and a second top surface 250a2 such that a top surface 250 of the first molding layer 250 has a step or step difference between the first top surface 250a1 and the second top surface 250a2.

The first top surface 250a1 of the first molding layer 250 may overlap the first semiconductor chip 110 in the vertical direction DR3. The second top surface 250a2 of the first molding layer 250 may be formed between a top surface 130a of the second insulating layer 130 and the first top surface 250a1 of the first molding layer 250. The second top surface 250a2 of the first molding layer 250 may be positioned a vertical level lower than that of the first top surface 250a1 of the first molding layer 250. Each of the first top surface 250a1 of the first molding layer 250 and the second top surface 250a2 of the first molding layer 250 may contact the second molding layer 160.

For example, the first top surface 250a1 of the first molding layer 250 may be coplanar with the top surface 130a of the second insulating layer 130. However, the present disclosure is not limited thereto. For example, the second top surface 250a2 of the first molding layer 250 may be positioned at a lower vertical level than that of the top surface 130a of the second insulating layer 130. However, the present disclosure is not limited thereto.

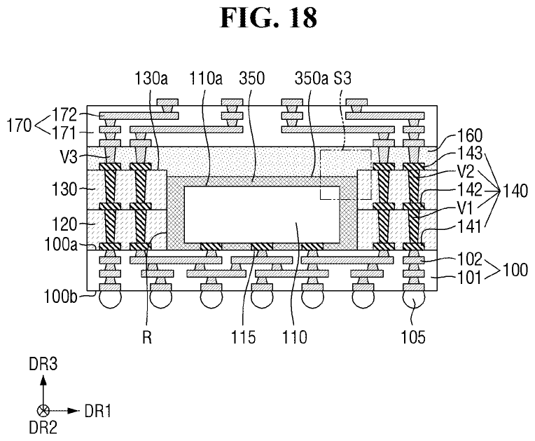

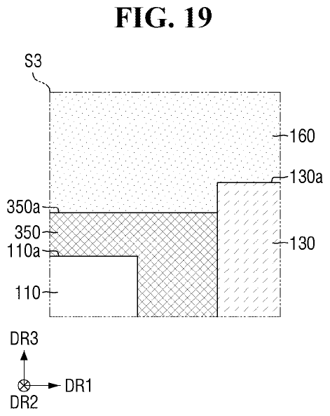

Hereinafter, a semiconductor package according to still further embodiments of the present disclosure will be described with reference to FIG. 18 and FIG. 19. The following descriptions will focus on differences from the semiconductor package as shown in FIG. 1 and FIG. 2.

FIG. 18 is a diagram illustrating a semiconductor package according to still further embodiments of the present disclosure. FIG. 19 is an enlarged view of a region S3 of FIG. 18.

Referring to FIG. 18 and FIG. 19, in the semiconductor package according to still further embodiments of the present disclosure, a top surface 350a of the first molding layer 350 may be positioned at a lower vertical level than that of the top surface 130a of the second insulating layer 130. For example, at least a portion of the second molding layer 160 may be disposed on the top surface 350a of the first molding layer 350 and inside the recess R. The portion of the second molding layer 160 disposed inside the recess R may be in contact with a sidewall of the second insulating layer 130.

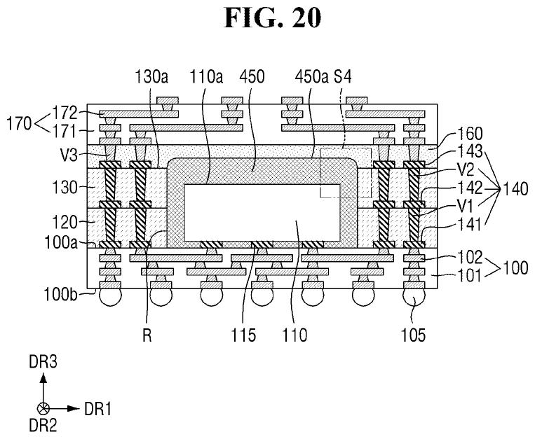

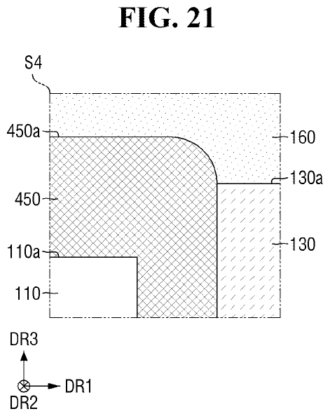

Hereinafter, a semiconductor packages according to still yet further embodiments of the present disclosure will be described with reference to FIG. 20 and FIG. 21. The following descriptions will focus on differences from the semiconductor package as shown in FIG. 1 and FIG. 2.

FIG. 20 is a diagram illustrating a semiconductor package according to still yet further some embodiments of the present disclosure. FIG. 21 is an enlarged view of a region S4 of FIG. 20.

Referring to FIG. 20 and FIG. 21, in the semiconductor package according to still yet further embodiments of the present disclosure, a top surface 450a of the first molding layer 450 may be positioned at a higher vertical level than that of the top surface 130a of the second insulating layer 130. That is, at least a portion of the first molding layer 450 may protrude upwardly in the vertical direction DR3 beyond the top surface 130a of the second insulating layer 130.

For example, the at least a portion of the first molding layer 450 protruding upwardly in the vertical direction DR3 beyond the top surface 130a of the second insulating layer 130 may not contact the top surface 130a of the second insulating layer 130. The second molding layer 160 may be in contact with the at least a portion of the first molding layer 450 protruding upwardly in the vertical direction DR3 beyond the top surface 130a of the second insulating layer 130.

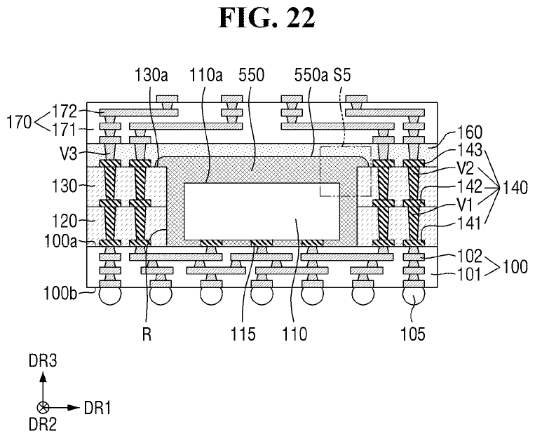

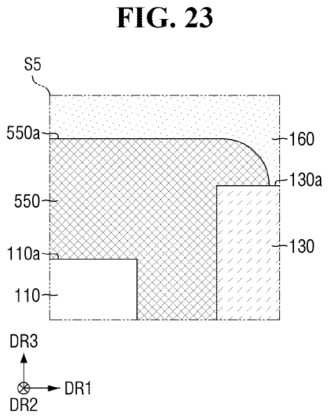

Hereinafter, a semiconductor package according to still yet further embodiments of the present disclosure will be described with reference to FIG. 22 and FIG. 23. The following descriptions will focus on differences from the semiconductor package as shown in FIG. 1 and FIG. 2.

FIG. 22 is a diagram illustrating a semiconductor package according to sill yet further embodiments of the present disclosure. FIG. 23 is an enlarged view of a region S5 of FIG. 22.

Referring to FIG. 22 and FIG. 23, in the semiconductor package according to still yet further some embodiments of the present disclosure, a top surface 550a of the first molding layer 550 may be positioned at a higher vertical level than that of the top surface 130a of the second insulating layer 130. That is, at least a portion of the first molding layer 550 may protrude upwardly in the vertical direction DR3 beyond the top surface 130a of the second insulating layer 130.

For example, the at least a portion of the first molding layer 550 protruding upwardly in the vertical direction DR3 beyond the top surface 130a of the second insulating layer 130 may be disposed on the top surface 130a of the second insulating layer 130. The portion of the first molding layer 550 disposed on the top surface 130a of the second insulating layer 130 may contact the top surface 130a of the second insulating layer 130. For example, the portion of the first molding layer 550 disposed on the top surface 130a of the second insulating layer 130 may be spaced apart from the connection structure 140. However, the present disclosure is not limited thereto. In further some embodiments, the portion of the first molding layer 550 disposed on the top surface 130a of the second insulating layer 130 may contact at least a portion of the connection structure 140. The second molding layer 160 may be in contact with the portion of the first molding layer 550 protruding upwardly in the vertical direction DR3 beyond the top surface 130a of the second insulating layer 130.

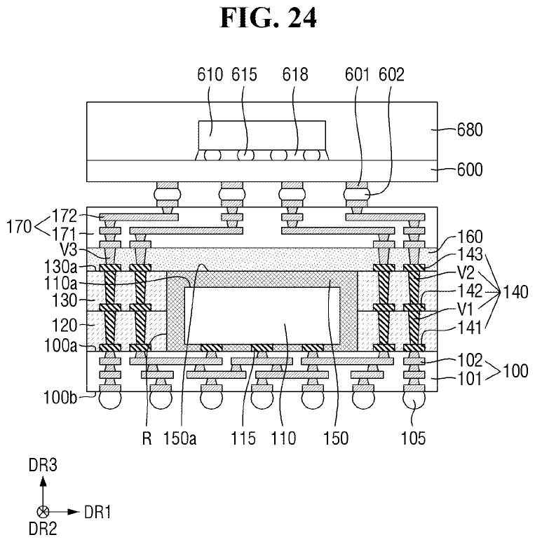

Hereinafter, a semiconductor package according to still yet further embodiments of the present disclosure will be described with reference to FIG. 24. The following descriptions will focus on differences from the semiconductor package as shown in FIG. 1 and FIG. 2.

FIG. 24 is a diagram illustrating a semiconductor package according to still yet further some embodiments of the present disclosure.

Referring to FIG. 24, in the semiconductor package according to still yet further exemplary embodiments of the present disclosure, an upper semiconductor package may be disposed on the second redistribution structure 170.

For example, the upper semiconductor package may include a substrate 600, a fourth connection pad 601, a second solder ball 602, a second semiconductor chip 610, a third solder ball 615, an underfill 618, and a third molding layer 680.

The substrate 600 may be disposed on the second redistribution structure 170. The substrate 600 may be embodied as, for example, a printed circuit board (PCB) or a ceramic substrate. However, the present disclosure is not limited thereto. When the substrate 600 is embodied as the printed circuit board, the substrate 600 may be made of phenol resin, epoxy resin, and/or polyimide. For example, the substrate 600 may include FR4, tetrafunctional epoxy, polyphenylene ether, epoxy/polyphenylene oxide, BT (bismaleimide triazine), thermount, cyanate ester, polyimide, and/or liquid crystal polymer. In some further embodiments, the substrate 600 may be an interposer.

A fourth connection pad 601 may be disposed on a bottom surface of the substrate 600. The fourth connection pad 601 may be disposed to face an exposed portion of the second redistribution layer 172 on a top surface of the second redistribution structure 170. For example, the fourth connection pad 601 may include a metal material such as copper (Cu), aluminum (Al), silver (Ag), tin (Sn), gold (Au), nickel (Ni), lead (Pb), titanium (Ti), or an alloy thereof. However, the present disclosure is not limited thereto.

The second solder ball 602 may be disposed between the fourth connection pad 601 and the second redistribution layer 172. The second solder ball 602 may electrically connect the fourth connection pad 601 and the second redistribution layer 172 to each other. The substrate 600 may be electrically connected to the second redistribution structure 170 via the second solder ball 602. The second solder ball 602 may include, for example, tin (Sn), indium (In), lead (Pb), zinc (Zn), nickel (Ni), gold (Au), silver (Ag), copper (Cu), antimony (Sb), bismuth (Bi) or combinations thereof. However, the present disclosure is not limited thereto.

The second semiconductor chip 610 may be disposed on a top surface of the substrate 600. For example, the second semiconductor chip 610 may be embodied as a logic semiconductor chip. For example, the second semiconductor chip 610 may be embodied as an application processor (AP) such as CPU (Central Processing Unit), GPU (Graphic Processing Unit), FPGA (Field-Programmable Gate Array), DSP (Digital Signal Processor), CP (Cryptographic Processor), a microprocessor, a microcontroller, or ASIC (Application-Specific IC), etc.

For example, the second semiconductor chip 610 may be embodied as a memory semiconductor chip. For example, the second semiconductor chip 610 may be embodied as a volatile memory such as DRAM (dynamic random access memory) or SRAM (static random access memory), or may be a non-volatile memory such as a flash memory, PRAM (Phase-change Random Access Memory), MRAM (Magnetoresistive Random Access Memory), FeRAM (Ferroelectric Random Access Memory) or RRAM (Resistive Random Access Memory).

The third solder ball 615 may be disposed between a top surface of the substrate 600 and the second semiconductor chip 610. The second semiconductor chip 610 may be electrically connected to the substrate 600 via the third solder ball 615. The third solder ball 615 may include, for example, tin (Sn), indium (In), lead (Pb), zinc (Zn), nickel (Ni), gold (Au), silver (Ag), copper (Cu), antimony (Sb), bismuth (Bi) or combinations thereof. However, the present disclosure is not limited thereto.

The underfill 618 disposed between a top surface of the substrate 600 and the second semiconductor chip 610 may surround a sidewall of the third solder ball 615. The underfill 618 may include, for example, an insulating polymer material such as an EMC (epoxy molding compound). However, the present disclosure is not limited thereto.

The third molding layer 680 may be disposed on a top surface of the substrate 600 so as to cover the second semiconductor chip 610 and the underfill 618. The third molding layer 680 may include, for example, an epoxy molding compound (EMC), or a hybrid material of two or more types of silicon. However, the present disclosure is not limited thereto.

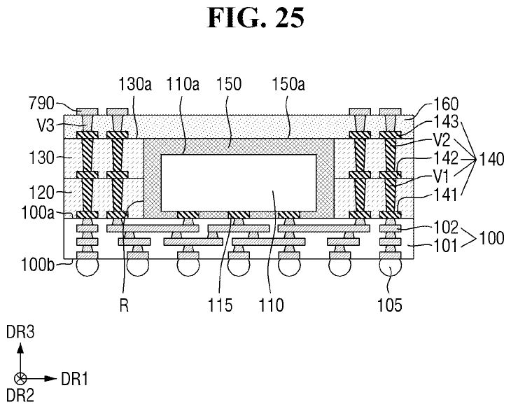

Hereinafter, a semiconductor package according to still yet further embodiments of the present disclosure will be described with reference to FIG. 25. The following descriptions will focus on differences thereof from the semiconductor package as shown in FIG. 1 and FIG. 2.

FIG. 25 is a diagram illustrating a semiconductor package according to still yet further embodiments of the present disclosure.

Referring to FIG. 25, in the semiconductor package according to still yet further embodiments of the present disclosure, the second redistribution structure (170 in FIG. 1) as an upper redistribution structure is absent or omitted.

For example, the top surface of the second molding layer 160 may be exposed. A fifth connection pad 790 may be disposed on the top surface of the second molding layer 160. The fifth connection pad 790 may be electrically connected to the third via V3 extending through the second molding layer 160 in the vertical direction DR3. The fifth connection pad 790 may be electrically connected to the connection structure 140 via the third via V3. For example, the fifth connection pad 790 may include a metal material such as copper (Cu), aluminum (Al), silver (Ag), tin (Sn), gold (Au), nickel (Ni), lead (Pb), titanium (Ti), or an alloy thereof. However, the present disclosure is not limited thereto.

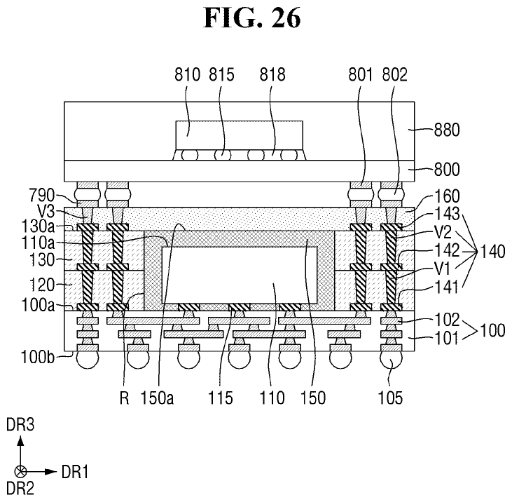

Hereinafter, a semiconductor package according to still yet further embodiments of the present disclosure will be described with reference to FIG. 26. The following descriptions will focus on differences from the semiconductor package as shown in FIG. 25.

FIG. 26 is a diagram illustrating a semiconductor package according to sill yet further embodiments of the present disclosure.

Referring to FIG. 26, in the semiconductor package according to still yet further embodiments of the present disclosure, an upper semiconductor package may be disposed on the second molding layer 160.

For example, the upper semiconductor package may include a substrate 800, a fourth connection pad 801, a second solder ball 802, a second semiconductor chip 810, a third solder ball 815, an underfill 818, and a third molding layer 880. For example, each of the substrate 800, the second semiconductor chip 810, the third solder ball 815, the underfill 818 and the third molding layer 880 may have the same structure as that of each of the substrate 600, the second semiconductor chip 610, the third solder ball 615, and the underfill 618 and the third molding layer 680 as shown in FIG. 24. Therefore, further description thereof will be omitted.

The fourth connection pad 801 may be disposed on a bottom surface of the substrate 800. The fourth connection pad 801 may be disposed to face the fifth connection pad 790. The second solder ball 802 may be disposed between the fourth connection pad 801 and the fifth connection pad 790. The second solder ball 802 may electrically connect the fourth connection pad 801 and the fifth connection pad 790 to each other. The substrate 800 may be electrically connected to the fifth connection pad 790 via the second solder ball 802.

Although embodiments of the present disclosure have been described with reference to the accompanying drawings, the present disclosure is not limited to the above embodiments, but may be implemented in various different forms. A person skilled in the art may appreciate that the present disclosure may be practiced in other forms without changing the technical spirit or essential characteristics of the present disclosure. Therefore, it should be appreciated that the embodiments as described above are not restrictive but are illustrative in all respects.

What is claimed is:

1. A semiconductor package comprising:
a first redistribution structure including a first redistribution layer;
a first semiconductor chip on the first redistribution structure;
an insulating layer adjacent a sidewall of the first semiconductor chip on the first redistribution structure, wherein the insulating layer is spaced apart from the first semiconductor chip in a horizontal direction;
a connection structure extending through the insulating layer in a vertical direction, wherein the connection structure is electrically connected to the first redistribution layer;
a first molding layer on a sidewall and a top surface of the first semiconductor chip; and
a second molding layer directly on each of a top surface of the insulating layer and a top surface of the first molding layer, wherein the second molding layer includes a material different from a material of the first molding layer,
wherein the top surface of the first semiconductor chip is lower than the top surface of the insulating layer relative to the first redistribution structure.

2. The semiconductor package of claim 1, wherein a viscosity of the first molding layer is lower than a viscosity of the second molding layer.

3. The semiconductor package of claim 1, wherein the connection structure does not contact the first molding layer.

4. The semiconductor package of claim 1, wherein at least a portion of the connection structure directly contacts the second molding layer.

5. The semiconductor package of claim 1, further comprising:
a second redistribution structure on the second molding layer, the second redistribution structure includes a second redistribution layer therein.

6. The semiconductor package of claim 5, further comprising:
a substrate on the second redistribution structure and electrically connected to the second redistribution structure; and
a second semiconductor chip on the substrate.

7. The semiconductor package of claim 1, wherein the top surface of the first molding layer is coplanar with the top surface of the insulating layer.

8. The semiconductor package of claim 1, wherein the top surface of the first molding layer includes:
a first top surface overlapping the first semiconductor chip in the vertical direction; and
a second top surface between the top surface of the insulating layer and the first top surface, wherein the second top surface is lower than the first top surface relative to the first redistribution structure.

9. The semiconductor package of claim 8, wherein the second top surface is lower than the top surface of the insulating layer relative to the first redistribution structure.

10. The semiconductor package of claim 1, wherein the top surface of the first molding layer is lower than the top surface of the insulating layer relative to the first redistribution structure.

11. The semiconductor package of claim 1, wherein the top surface of the first molding layer is higher than the top surface of the insulating layer relative to the first redistribution structure.

12. The semiconductor package of claim 11, wherein at least a portion of the first molding layer directly contacts the top surface of the insulating layer.

13. A semiconductor package comprising:
a first redistribution structure including a first redistribution layer;
an insulating layer on the first redistribution structure;
a recess in the insulating layer;
a first semiconductor chip in the recess and spaced apart from the insulating layer in a horizontal direction, wherein a top surface of the first semiconductor chip is lower than a top surface of the insulating layer relative to the first redistribution structure;
a first molding layer on a sidewall and the top surface of the first semiconductor chip in the recess, wherein the first molding layer is free of a filling material including silicon (Si) particles; and
a second molding layer directly on each of the top surface of the insulating layer and a top surface of the first molding layer, wherein the second molding layer comprises the filling material including silicon (Si) particles.

14. The semiconductor package of claim 13, further comprising:
a connection structure extending through the insulating layer in a vertical direction, wherein the connection structure is electrically connected to the first redistribution layer, and the connection structure does not contact the first molding layer.

15. The semiconductor package of claim 13, wherein the first molding layer does not contact the top surface of the insulating layer.

16. The semiconductor package of claim 13, further comprising:
a second redistribution structure on the second molding layer, wherein the second redistribution structure includes a second redistribution layer therein.

17. The semiconductor package of claim 13, wherein the top surface of the first molding layer includes:
a first top surface overlapping the first semiconductor chip in a vertical direction; and
a second top surface between the top surface of the insulating layer and the first top surface, wherein the second top surface is lower than the first top surface relative to the first redistribution structure.

18. The semiconductor package of claim 13, further comprising:
a connection structure extending through the insulating layer in a vertical direction, wherein the connection structure is electrically connected to the first redistribution layer;
a connection pad on a top surface of the second molding layer; and
a via extending through the second molding layer in the vertical direction, wherein the via electrically connects the connection structure to the connection pad.

19. The semiconductor package of claim 18, further comprising:
a substrate on the second molding layer and electrically connected to the connection pad; and
a second semiconductor chip on the substrate.

20. A semiconductor package comprising:
a first redistribution structure including a first redistribution layer;
a first semiconductor chip on the first redistribution structure;
an insulating layer adjacent a sidewall of the first semiconductor chip on the first redistribution structure, wherein the insulating layer is spaced apart from the first semiconductor chip in a horizontal direction;
a connection structure extending through the insulating layer in a vertical direction, wherein the connection structure is electrically connected to the first redistribution layer;
a first molding layer on the sidewall and a top surface of the first semiconductor chip, wherein the first molding layer is free of a filling material including silicon (Si) particles, and the first molding layer does not contact the connection structure;
a second molding layer directly on each of a top surface of the insulating layer and a top surface of the first molding layer, wherein the second molding layer directly contacts at least a portion of the connection structure, and the second molding layer comprises the filling material including silicon (Si) particles; and
a second redistribution structure on the second molding layer, wherein the second redistribution structure includes a second redistribution layer therein,
wherein the top surface of the first semiconductor chip is lower than the top surface of the insulating layer relative to the first redistribution structure, and
wherein the top surface of the first molding layer is coplanar with the top surface of the insulating layer.
